(19) United States
(12) Patent Application Publication
(10) Pub. No.: US 2008/0150000 A1
(43) Pub. Date: Jun. 26, 2008

(54) MEMORY SYSTEM WITH SELECT GATE ERASE

(75) Inventors: YouSeok Suh, Cupertino, CA (US); Hidehiko Shiraiwa, San Jose, CA (US); Kuo-Tung Chang, Saratoga, CA (US); Lei Xue, Sunnyvale, CA (US); Meng Ding, Sunnyvale, CA (US); Amol Ramesh Joshi, Sunnyvale, CA (US); Shenqing Fang, Fremont, CA (US)

Correspondence Address: LAW OFFICES OF MIKIO ISHIMARU, 333 W. EL CAMINO REAL, SUITE 330, SUNNYVALE, CA, 94087, US

(73) Assignee: SPANSION LLC, Sunnyvale, CA (US)

(21) Appl. No.: 11/614,839

(22) Filed: Dec. 21, 2006

(51) Int. Cl. H01L 29/792; H01L 21/28

(52) U.S. Cl. 257/324; 438/591; 257/E29.309; 257/E21.18

(57) ABSTRACT

A memory system includes a substrate, forming a first insulator over the substrate, forming a charge trap layer, having a composition for setting a predetermined electrical charge level, over the first insulator, and forming a second insulator over the charge trap layer.

### TECHNICAL FIELD

The present invention relates generally to memory systems, and more particularly to a system for non-volatile memory.

### BACKGROUND ART

Electronics devices are so pervasive and so many of them require data storage. The needs for this storage seem boundless in so many devices, such as smart phones, personal digital assistants, location based devices, digital cameras, or music players. Not only are the requirements growing in capacity but also in retention. Thus, various types of non-volatile memories have been developed including electrically erasable programmable read only memory (EEPROM) and electrically programmable read only memory (EPROM). Each type of memory had advantages and disadvantages. EEPROM can be easily erased without extra exterior equipment but with reduced data storage density, lower speed, and higher cost. EPROM, in contrast, is less expensive and has greater density but lacks erasability.

Another type of memory called “Flash” EEPROM, or Flash memory, has become popular as it combines advantages of high density and low cost characteristic of EPROM but with the electrical erasability of EEPROM. Flash memory can be rewritten and hold its contents without supplying continuous power. Contemporary Flash memories are designed in a floating gate or a charge trapping architecture. Each of the architectures has advantages and disadvantages.

The floating gate architecture offers implementation simplicity. This architecture embeds a gate structure, called a floating gate, inside a conventional metal oxide semiconductor (MOS) transistor gate stack. Electrons can be injected and stored in the floating gate as well as erased using an electrical field or ultraviolet light. The stored informing may be interpreted as a value “0” or “1” from the threshold voltage value depending upon charge stored in the floating gate. As the demand for Flash memories increases, the Flash memories must scale with new semiconductor processes. However, new semiconductor process causes a reduction of key feature sizes in Flash memories of the floating gate architecture that result in decrease in data retention.

The charge trapping architecture offers improved scalability with new semiconductor processes versus the floating gate architecture. One implementation of the charge trapping architecture is a silicon-oxide-nitride-oxide semiconductor (SONOS) where charge is trapped in a nitride layer. Leakage and charge-trapping efficiency are two major parameters considered in device performance evaluation. Charge-trapping efficiency determines if enough charge remains in the storage nodes after program/erase operation and is reflected in retention characteristics. It is especially critical when the leakage behavior of storage devices is inevitable.

SONOS Flash memories suffer from poor programming performance. Silicon content in the nitride layer improves the programming and erasing performances but offers poor data retention. Although silicon content plays an important role in charge-trapping efficiency, it does not have same constructive effect on leakage characteristics. The interface between the charge trapping layer with both the top blocking oxide layer and the bottom tunneling oxide layer present both scaling and functional problems as well as add cost to the manufacturing process.

There continue to be concerns regarding the erasing and programming processes, since too high a voltage or too much current can damage the memory cell. In order to perform an erase without damaging the memory cell a process of erase, verify, and repeat is used. This iterative approach helps to protect the individual memory cells, but severely restricts the performance of the memory array.

Similarly, when data is programmed into the memory cell it is difficult to accurately end the write process at the proper resistance value. Applying too much current may damage the memory cell and applying too little current yields unreliable data retention. This conventional approach of updating memory cells is too slow. The erasing and programming limitations present significant issues to non-volatile memory manufacturers. A new approach must be found in order to increase the performance of non-volatile memory.

Thus, a need still remains for a memory system to improve erase performance. In view of the ever-increasing commercial competitive pressures, along with growing consumer expectations and the diminishing opportunities for meaningful product differentiation in the marketplace, it is critical that answers be found for these problems. Additionally, the need to save costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a substrate, forming a first insulator over the substrate, forming a charge trap layer, having a composition for setting a predetermined electrical charge level, over the first insulator, and forming a second insulator over the charge trap layer.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a top plan view of a memory system in an embodiment of the present invention;

FIG. 2 is a top plan view of a memory system in an alternative embodiment of the present invention;

FIG. 3 is a cross-sectional view of the memory system in a programming erase phase;

FIG. 4 is a cross-sectional view of the structure of FIG. 3 in a programming initialization phase;

FIG. 5 is a cross-sectional view of the memory system in a processing erase phase;

FIG. 6 is a cross-sectional view of the structure of FIG. 5 in a processing initialization phase;

FIGS. 7A, 7B, and 7C are schematic views of electronics systems as examples in which various aspects of the present invention can be implemented; and

FIG. 8 is a flow chart of a memory system for manufacturing the memory system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Where multiple embodiments are disclosed and described, having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the invention, regardless of its orientation. The term “vertical” refers to a direction perpendicular to the horizontal as just defined. Terms, such as “on” “above”, “below”, “bottom”, “top”, “side” (as in “sidewall”), “higher”, “lower”, “upper”, “over”, and “under”, are defined with respect to the horizontal plane.

The term “on” as used herein means and refers to direct contact among elements. The term “processing” as used herein includes deposition of material, patterning, exposure, development, etching, cleaning, and/or removal of the material or trimming as required in forming a described structure. The term “system” as used herein means and refers to the method and to the apparatus of the present invention in accordance with the context in which the term is used.

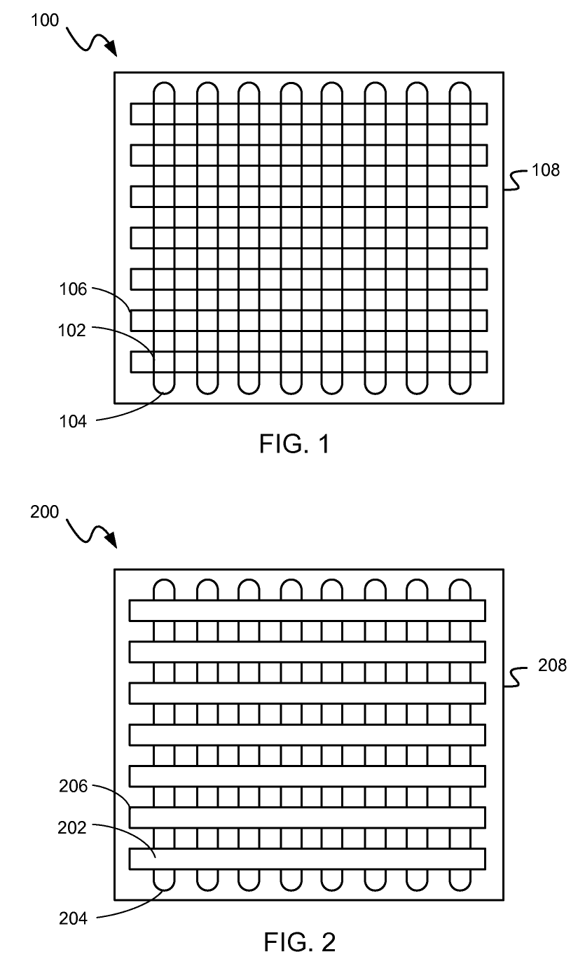

Referring now to FIG. 1, therein is shown a top plan view of a memory system 100 in an embodiment of the present invention. The memory system 100 may be used in a number of different memory architectures, such as NOR or NAND architecture. The memory system 100 includes a charge trap layer 102, such as silicon nitride, in an overlap region of a bitline 104, such as a source-drain and a wordline 106. The charge trap layer 102 is formed having a predetermined composition, such as an optimized composition of Si₁₋ₓNₓ: x=0˜1, for adjusting threshold voltage. The charge trap layer 102 provides storage of an electrical charge, such as electrons.

The memory system 100 can also includes a semiconductor substrate 108, such as a p-type substrate, having a first region (not shown), such as an n-type region, and a second region (not shown), such as an n-type region. The first region can function as a source or a drain while the second region can function as a drain or a source though the compliment of the first region. The first region, the second region, or a combination thereof can connect to the bitline 104 providing access to the memory system 100 for decoding processes. Signals on the wordline 106 and connection of the bitline 104 to an electrical source or drain can enable the memory system 100 to read, program or erase the charge trap layer 102.

For illustrative purposes, the memory system 100 is shown having fifty-six regions of the charge trap layer 102 for storing an electrical charge, although it is understood that any number of the charge trap layer 102 may be included. It is also understood that each of the charge trap layer 102 may provide storage for any number of electrical charges.

It has been discovered that the predetermined composition of the charge trap layer 102 provides adjustment of threshold voltage.

Referring now to FIG. 2, therein is shown a top plan view of a memory system 200 in an alternative embodiment of the present invention. The memory system 200 may be used in a number of different memory architectures, such as NOR or NAND architecture. The memory system 200 includes a charge trap layer 202, such as a silicon nitride, a bitline 204, such as a source-drain and a wordline 206. The charge trap layer 202 is formed having a predetermined composition for adjusting threshold voltage. The charge trap layer 202 is formed under the wordline 206 and provides storage of an electrical charge, such as electrons.

The memory system 200 can also includes a semiconductor substrate 208, such as a p-type substrate, having a first region (not shown), such as an n-type region, and a second region (not shown), such as an n-type region. The first region can function as a source or a drain while the second region can function as a drain or a source though the compliment of the first region. The first region, the second region, or a combination thereof can connect to the bitline 204 providing access to the memory system 200 for decoding processes. Signals on the wordline 206 and connection of the bitline 204 to an electrical source or drain can enable the memory system 200 to read, program or erase the charge trap layer 202.

For illustrative purposes, the memory system 200 is shown having seven regions of the charge trap layer 202 for storing an electrical charge, although it is understood that any number of the charge trap layer 202 may be included. It is also understood that each of the charge trap layer 202 may provide storage for any number of electrical charges.

It has been discovered that the predetermined composition of the charge trap layer 202 provides adjustment of threshold voltage.

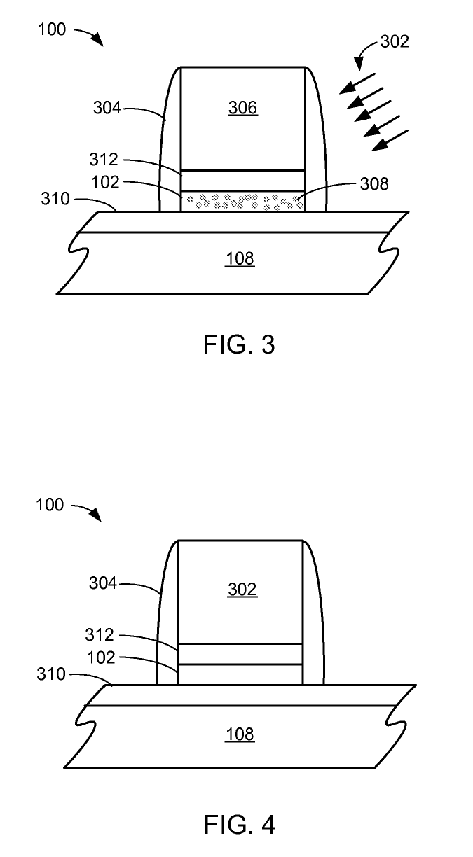

Referring now to FIG. 3, therein is shown a cross-sectional view of the memory system 100 in a programming erase phase. The memory system 100 can include a radiation source 302, such as an ultraviolet light source. The memory system 100 can also include a spacer 304 such as a nitride spacer near the charge trap layer 102. The memory system also includes a gate layer 306, such as a gate electrode of polysilicon. The gate layer 306 can be electrically or physically equivalent to the wordline 106. A charge 308 can be stored in the charge trap layer 102 or the spacer 304 resulting from a process such as programming. The radiation source 302 can be applied to erase the charge 308 of the charge trap layer 102 or the spacer 304.

As an example, a first insulator 310 can be formed over the semiconductor substrate 108. Further, the charge trap layer 102 can be formed over the first insulator 310 and the semiconductor substrate 108. Yet further, a second insulator 312 can be formed over the charge trap layer 102, the first insulator 310, and the semiconductor substrate 108. Yet further, the gate layer 306 can be formed over the second insulator 312.

The charge trap layer 102 can be insulated by the first insulator 310 and the second insulator 312. For illustrative purposes, the first insulator 310 is shown as extending beyond the spacer 304 although it is understood that the first insulator 310 may be formed to any extent.

Referring now to FIG. 4, therein is shown a cross-sectional view of the structure of FIG. 3 in a programming initialization phase. The memory system 100 includes the charge trap layer 102 isolated by the first insulator 310 and the second insulator 312. The charge trap layer 102 provide an electrical charge level substantially the same as that of an intrinsic state of the charge trap layer 102. The electrical charge level of the charge trap layer 102 or the spacer 304 includes limiting or substantially eliminating the charge 308 of FIG. 3. Further, an electrical trigger level, such as a threshold voltage, of the charge trap layer 102 after application of the radiation source 302 of FIG. 3 is predetermined by the composition of the charge trap layer 102.

It has been discovered that the predetermined composition of the charge trap layer 102 and the isolation of the charge trap layer 102 provides a predetermined voltage after ultraviolet erase. Further, it has been discovered that the predetermined composition of the charge trap layer 102 provides controlled and uniform electrical trigger level distribution.

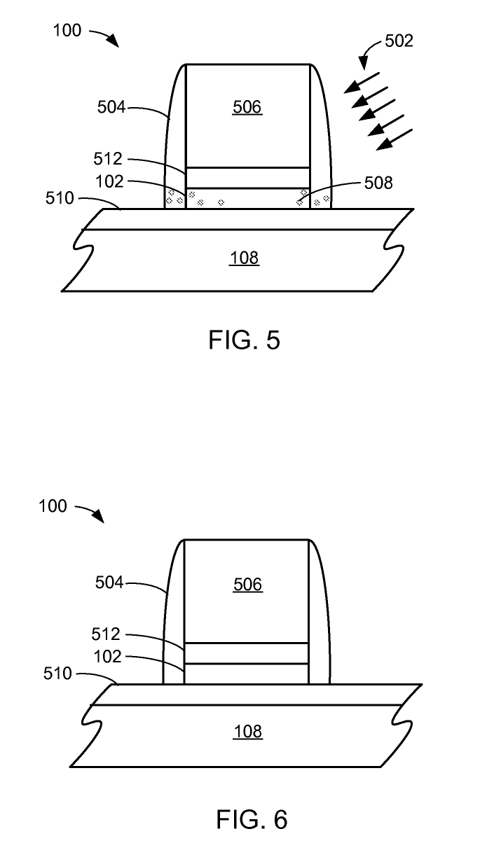

Referring now to FIG. 5, therein is shown a cross-sectional view of the memory system 100 in a processing erase phase. The memory system 100 can include a radiation source 502, such as an ultraviolet light source. The memory system 100 can also include a spacer 504 such as a nitride spacer near the charge trap layer 102. The memory system also includes a gate layer 506, such as a gate electrode of polysilicon. The gate layer 506 can be electrically or physically equivalent to the wordline 106. A charge 508 can be stored in the charge trap layer 102 or the spacer 504 resulting from a process such as semiconductor processing. The radiation source 502 can be applied to erase the charge 508 of the charge trap layer 102 or the spacer 504.

As an example, a first insulator 510 can be formed over the semiconductor substrate 108. Further, the charge trap layer 102 can be formed over the first insulator and the semiconductor substrate 108. Yet further, a second insulator 512 can be formed over the charge trap layer 102, the first insulator 510, and the semiconductor substrate 108. Yet further, the gate layer 506 can be formed over the second insulator 512.

The charge trap layer 102 can be insulated by the first insulator 510 and the second insulator 512. For illustrative purposes, the first insulator 510 is shown as extending beyond the spacer 504 although it is understood that the first insulator 510 may be formed to any extent.

Referring now to FIG. 6, therein is shown a cross-sectional view of the structure of FIG. 5 in a processing initialization phase. The memory system 100 includes the charge trap layer 102 isolated by the first insulator 510 and the second insulator 512. The charge trap layer 102 and provides an electrical charge level substantially the same as that of an intrinsic state of the charge trap layer 102. The electrical charge level of the charge trap layer 102 or the spacer 504 includes limiting or substantially eliminating the charge 508 of FIG. 5. Further, the electrical trigger level, such as a threshold voltage, of the charge trap layer 102 after application of the radiation source 502 of FIG. 5 is predetermined by the composition of the charge trap layer 102.

It has been discovered that the predetermined composition of the charge trap layer 102 and the isolation of the charge trap layer 102 provides a predetermined voltage after ultraviolet erase. Further, it has been discovered that the predetermined composition of the charge trap layer 102 provides uniform and controlled electrical trigger level distribution.

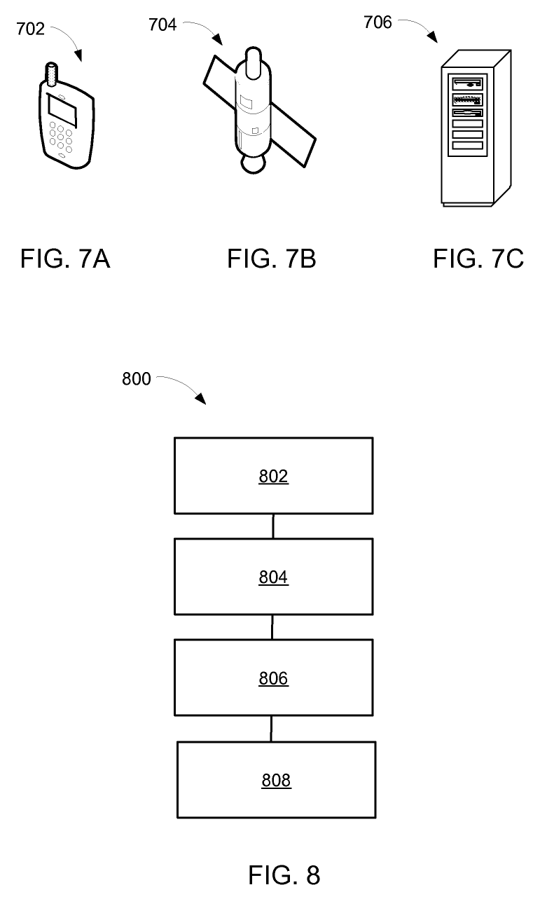

Referring now to FIGS. 7A, 7B, and 7C therein are shown schematic views of electronics systems as examples in which various aspects of the present invention can be implemented. The electronics systems can be any system performing any function including creation, transportation, transmittal, modification, or storage of data. As examples, electronics systems such as a smart phone 702, a satellite 704, and a compute system 706 can include the present invention. For example, information created, transported, or stored on the smart phone 702 can be transmitted to the satellite 704. Similarly, the satellite 704 can transmit or modify the information to the compute system 706 wherein the information can be stored, modified, or transmitted by the compute system 706.

Referring now to FIG. 8, therein is shown a flow chart of a memory system 800 for manufacturing the memory system 100 in an embodiment of the present invention. The system 800 includes providing a substrate in a block 802; forming a first insulator over the substrate in a block 804; forming a charge trap layer, having a composition for setting a predetermined electrical charge level, over the first insulator in a block 806; and forming a second insulator over the charge trap layer in a block 808.

In greater detail, a system to provide the method and apparatus of the memory system 100, in an embodiment of the present invention, is performed as follows:
1. Providing a semiconductor substrate.
2. Forming a first insulator over the semiconductor substrate.
3. Forming a charge trap layer having a predetermined composition for controlling an electrical trigger level over the first insulator layer.
4. Forming a second insulator isolating the charge-storage layer on a side opposite the first insulator.
5. Applying a radiation source over the first insulator, the charge trap layer, and the second insulator.

The present invention thus has numerous aspects.

A principle aspect of the present invention is that when the charge trap layer is isolated and exposed to radiation, the charge trap layer is discharged. The present invention is unique in that radiation exposure to a charge trap layer is known to result in charging the charge trap layer.

Another aspect is that the present invention is that when the charge trap layer is discharged, the trap charge layer attains an electrical level of intrinsic state of the trap charge layer. The present invention provides a solution to several processes such as plasma etch or deposition increasing charging in the charge trap layer.

Another aspect of the present invention is that the intrinsic state of the trap charge layer is determined by the composition of the trap charge layer. The present invention provides uniform threshold voltages with the need for using radiation to tighten up the threshold voltage distribution.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the memory system method and apparatus of the present invention furnish important and heretofore unknown and unavailable solutions, capabilities, and functional aspects for memory systems. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. A memory system comprising:
providing a substrate;
forming a first insulator over the substrate;
forming a charge trap layer, having a composition for setting a predetermined electrical charge level, over the first insulator; and
forming a second insulator over the charge trap layer.

2. The system as claimed in claim 1 further comprising forming a gate layer over the second insulator.

3. The system as claimed in claim 1 further comprising forming a spacer adjacent to the charge trap layer, and the second insulator.

4. The system as claimed in claim 1 further comprising applying radiation on the charge trap layer.

5. The system as claimed in claim 1 wherein forming the charge trap layer includes forming a nitride layer.

6. A memory system comprising:
providing a semiconductor substrate;
forming a first insulator over a semiconductor substrate;
forming a charge trap layer, having a composition for tuning a predetermined electrical trigger level, over the first insulator;
forming a second insulator isolating the charge trap layer on a side opposite the first insulator; and
applying a radiation source over the first insulator, the charge trap layer, and the second insulator.

7. The system as claimed in claim 6 further comprising forming a polysilicon gate electrode over the second insulator.

8. The system as claimed in claim 6 further comprising forming a nitride spacer adjacent to the charge trap layer, and the second insulator.

9. The system as claimed in claim 6 wherein applying the radiation source includes applying an ultraviolet light source.

10. The system as claimed in claim 6 wherein forming the charge trap layer includes forming a silicon nitride layer.

11. A memory system comprising:
a substrate;
a first insulator over the substrate;
a charge trap layer, having a composition for setting a predetermined electrical charge level, over the first insulator; and
a second insulator over the charge trap layer.

12. The system as claimed in claim 11 further comprising a gate layer over the second insulator.

13. The system as claimed in claim 11 further comprising a spacer adjacent to the charge trap layer, and the second insulator.

14. The system as claimed in claim 11 further comprising radiation on the charge trap layer.

15. The system as claimed in claim 11 wherein the charge trap layer is a nitride layer.

16. The system as claimed in claim 11 wherein:
the substrate is a semiconductor substrate;
the first insulator layer is over a semiconductor substrate;
the charge trap layer has a composition for tuning a predetermined electrical trigger level;
the second insulator isolates the charge-storage layer on a side opposite the first insulator; and further comprising:
a radiation source over the first insulator, the charge trap layer and the second insulator.

17. The system as claimed in claim 16 further comprising a polysilicon gate electrode over the second insulator.

18. The system as claimed in claim 16 further comprising a nitride spacer adjacent to the charge trap layer, and the second insulator.

19. The system as claimed in claim 16 wherein the radiation source includes an ultraviolet light source.

20. The system as claimed in claim 16 wherein the charge trap layer includes a silicon nitride layer.
